(19) United States
(12) Patent Application Publication
(10) Pub. No.: US 2025/0275163 A1
(43) Pub. Date: Aug. 28, 2025

(54) MANUFACTURING METHOD OF HIGH POWER SEMICONDUCTOR DEVICE

(71) Applicant: SK keyfoundry Inc., Cheongju-si (KR)

(72) Inventors: Sun Hak LEE, Cheongju-si (KR); Soo Chang KANG, Cheongju-si (KR); Jong Sun MAENG, Cheongju-si (KR); Mun Sik OH, Cheongju-si (KR); Seong Yong JANG, Cheongju-si (KR); So Ra MIN, Cheongju-si (KR)

(73) Assignee: SK keyfoundry Inc., Cheongju-si (KR)

(21) Appl. No.: 18/918,753

(22) Filed: Oct. 17, 2024

(30) Foreign Application Priority Data
Feb. 22, 2024 (KR) 10-2024-0025866

(51) Int. Cl. H01L 29/66; H01L 21/02; H01L 21/283; H01L 29/20; H01L 29/40

(52) U.S. Cl. CPC H10D 30/015; H01L 21/02315; H01L 21/02664; H01L 21/283; H01L 21/02164; H01L 21/0217; H01L 21/02178; H10D 62/8503; H10D 64/112

(57) ABSTRACT

A method for manufacturing a high power semiconductor device includes etching a P—GaN layer on a semiconductor substrate including a GaN layer, an AlGaN layer, and a P—GaN layer to form a first P—GaN layer, a first field plate, and a second P—GaN layer on a surface of the AlGaN layer. The method further includes treating the surface of the AlGaN layer with an ammonia plasma and forming a first passivation layer thereon. The method further includes forming a second passivation layer including a single or two or more layers having a high permittivity on the first passivation layer.

### CROSS-REFERENCE TO RELATED APPLICATION

This application claims the benefit under 35 U.S.C. § 119 (a) of Korean Patent Application No. 10-2024-0025866, filed on Feb. 22, 2024, the entire disclosure of which is incorporated herein by reference for all purposes.

### BACKGROUND

### 1. Field

The following description relates to a method of manufacturing a semiconductor device suitable for high power (high voltage, high current) products.

### 2. Discussion of Related Art

The statements in this section merely provide background information related to the present disclosure and do not necessarily constitute prior art.

In the past, silicon (Si) material devices have been used to fabricate high power semiconductor devices. However, the physical constraints of silicon materials have limited the ability to reduce the on-resistance (Ron) while simultaneously miniaturizing the devices.

As a result, attempts have been made to develop semiconductor devices using silicon carbide (SiC) or gallium nitride (GaN) to enable higher power density, higher efficiency, faster switching speeds, and smaller devices. GaN, in particular, is known for its high compatibility, which makes it suitable for manufacturing high-power devices. GaN has a larger electric field and energy gap than other materials, making it resistant to high internal pressures. It also has high electron mobility and electron velocity, making it excellent for high-frequency operation.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a method of manufacturing a high power semiconductor device includes: preparing a semiconductor substrate on which a silicon layer, a gallium nitride (GaN) buffer layer, a GaN layer, an aluminum gallium nitride (AlGaN) layer, and a P—GaN layer are sequentially stacked; etching the P—GaN layer and then simultaneously forming a first P—GaN layer, a first field plate, and a second P—GaN layer on a surface of the AlGaN layer; forming a first passivation layer on the semiconductor substrate; etching the first passivation layer and then forming a source metal and a drain metal; forming a second passivation layer after forming the source metal and the drain metal; forming a gate metal in a gate contact region formed by etching the second passivation layer; forming an insulating layer after the forming of the gate metal; and forming a field plate metal on the insulating layer; and forming third field plates on both sides of the drain metal and a fourth field plate between the gate metal and the first field plate by performing an etching process on the field plate metal.

The manufacturing method may further include: before forming the first passivation layer, performing an ammonia plasma treatment on a surface of the AlGaN layer; and performing an annealing process after the ammonia plasma treatment.

The first passivation layer may be formed of at least one of SiO₂, SiN, Al₂O₃, and aluminum nitride (AlN).

The second passivation layer may be formed by combining one or more high dielectric thin films, and any one of SiO₂/SiN, SiN/SiO₂, SiN/SiO₂/SiN, SiO₂/SiN/SiO₂, Al₂O₃, and aluminum nitride (AlN) may be selected to form the second passivation layer.

The gate contact region formed by the etching of the second passivation layer may have an opening width smaller than an opening width of the first P—GaN layer.

The source metal may be formed to have a smaller width than the drain metal.

The source metal and the drain metal may be formed of one of Ti/Al/Ni/Au, Ti/Al/TiN, and Ti/Al/W. The Tin metal may have a thickness of 50 to 400 Å, and the Al metal may have a thickness of 500 to 3000 Å.

The second field plate may be simultaneously formed when the gate metal is formed.

The second field plate may be formed closer to the gate metal than the first field plate.

The manufacturing method may further include: after the forming of the third field plates and the fourth field plate, forming an interlayer insulating layer; patterning the interlayer insulating layer and then forming a contact plug; and forming a metal line connected to the contact plug.

The semiconductor device may include a drain region having a hole injection region and a non-hole injection region, and the second P—GaN layer is located in the hole injection region.

In another general aspect, a method of manufacturing a high power semiconductor device includes: stacking and forming a AlGaN layer and a P—GaN layer on a semiconductor substrate; etching the P—GaN layer and then simultaneously forming a gate P—GaN layer, a first field plate, and a drain P—GaN layer on a surface of the AlGaN layer; treating the surface of the AlGaN layer with a plasma; forming a first passivation layer on the surface-treated AlGaN layer and the semiconductor substrate; etching the first passivation layer and then forming a source metal and a drain metal; forming a second passivation layer on the source and drain metals and the first passivation layer; etching the second passivation layer and then simultaneously forming a gate metal and a second field plate; forming an insulating layer after the forming of the gate metal and the second field plate; forming third field plates on both sides of the drain metal and a fourth field plate between the gate metal and the first field plate; forming an interlayer insulating layer on the third field plates and the fourth field plate; patterning the interlayer insulating layer and then forming a contact plug; and forming a metal line connected to the contact plug.

The forming of the gate metal may include forming a gate contact region. An opening width of the gate contact region may be formed to be smaller than an opening width of the gate P—GaN layer.

The source metal may be formed to have a smaller width than the drain metal.

The first passivation layer may be formed of at least one of SiO₂, SiN, Al₂O₃, and aluminum nitride (AlN).

The second passivation layer may be formed by combining one or more high dielectric thin films, and any one of SiO₂/SiN, SiN/SiO₂, SiN/SiO₂/SiN, SiO₂/SiN/SiO₂, Al₂O₃, and aluminum nitride (AlN) may be selected to form the second passivation layer.

The manufacturing method may further include performing a heat treatment on the surface of the AlGaN layer after the surface is treated with the plasma.

The semiconductor device may include a drain region having a hole injection region and a non-hole injection region. The drain P—GaN layer may be located in the hole injection region to operate as a hole injection.

The gate metal may be formed in contact with an upper surface of the gate P—GaN layer, and a width of the gate metal may be equal to a width of the gate P—GaN layer.

The drain metal may be formed in contact with an upper part of the drain P—GaN layer, and a width of each of the third field plates formed on an upper part of the drain metal may be equal to a width of the drain P—GaN layer.

The AlGaN layer formed below the gate P—GaN layer, the first field plate, and the drain P—GaN layer may be thicker than other regions of the P—GaN layer.

Other features and aspects will be apparent from the following detailed description, the drawings, and the claims.

### BRIEF DESCRIPTION OF THE DRAWINGS

FIG. 1 illustrates a plan view of a semiconductor device according to one or more embodiments of the present disclosure.

FIG. 2 (a) illustrates a cross-sectional view along the line A-A′ in the plan view of FIG. 1, while FIG. 2 (b) illustrates a cross-sectional view along the line B-B′ in the plan view of FIG. 1.

FIGS. 3 to 18 are process diagrams that illustrate the manufacturing of a semiconductor device according to one or more embodiments of the present disclosure.

Throughout the drawings and the detailed description, unless otherwise described or provided, the same reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness, noting that omissions of features and their descriptions are also not intended to be admissions of their general knowledge.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application. The use of the term “may” herein with respect to an example or embodiment, e.g., as to what an example or embodiment may include or implement, means that at least one example or embodiment exists where such a feature is included or implemented, while all examples are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

Spatially relative terms such as “above,” “upper,” “below,” and “lower” may be used herein for ease of description to describe one element's relationship to another element as shown in the figures. Such spatially relative terms are intended to encompass different orientations of the device in use or operation in addition to the orientation depicted in the figures. For example, if the device in the figures is turned over, an element described as being “above” or “upper” relative to another element will then be “below” or “lower” relative to the other element. Thus, the term “above” encompasses both the above and below orientations depending on the spatial orientation of the device. The device may also be oriented in other ways (for example, rotated 90 degrees or at other orientations), and the spatially relative terms used herein are to be interpreted accordingly.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

Due to manufacturing techniques and/or tolerances, variations of the shapes shown in the drawings may occur. Thus, the examples described herein are not limited to the specific shapes shown in the drawings, but include changes in shape that occur during manufacturing.

The features of the examples described herein may be combined in various ways as will be apparent after an understanding of the disclosure of this application. Further, although the examples described herein have a variety of configurations, other configurations are possible as will be apparent after an understanding of the disclosure of this application.

The example is to solve the aforementioned problem. The example may provide a method of manufacturing a semiconductor device employing GaN material, known for its high compatibility with high power devices.

The technical problems of the present disclosure are not limited to those mentioned above, and other technical problems not mentioned will be apparent to those skilled in the art from the following description.

A detailed description is given below, with reference to attached drawings.

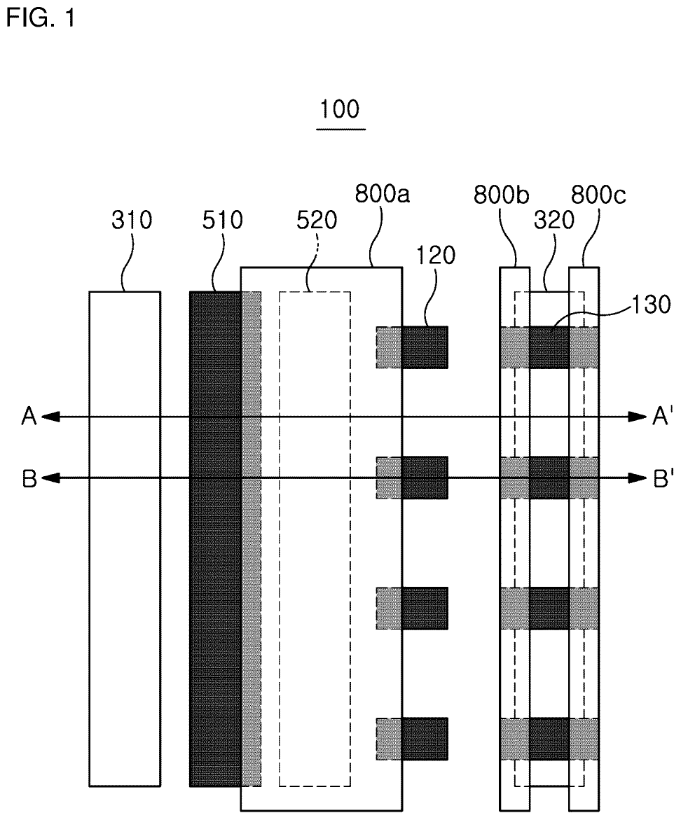

FIG. 1 illustrates a plan view of a semiconductor device according to one or more embodiments of the present disclosure. The description of the cross-sectional view along the line A-A′ and the cross-sectional view along the line B-B′ shown in FIG. 1 will be described below.

Referring to FIG. 1, a semiconductor device may include a semiconductor substrate 100, a source region 310, a drain region 320, a gate region 510, a first field plate 120, a second field plate 520, third field plates 800b, 800c, and a fourth field plate 800a.

The semiconductor substrate 100 may have a structure in which one or more layers are stacked. According to an example, the semiconductor substrate 100 may have a structure comprising, from bottom to top, a silicon layer—GaN buffer layer—GaN layer—AlGaN layer—P—GaN layer. The silicon layer may be SiC or sapphire.

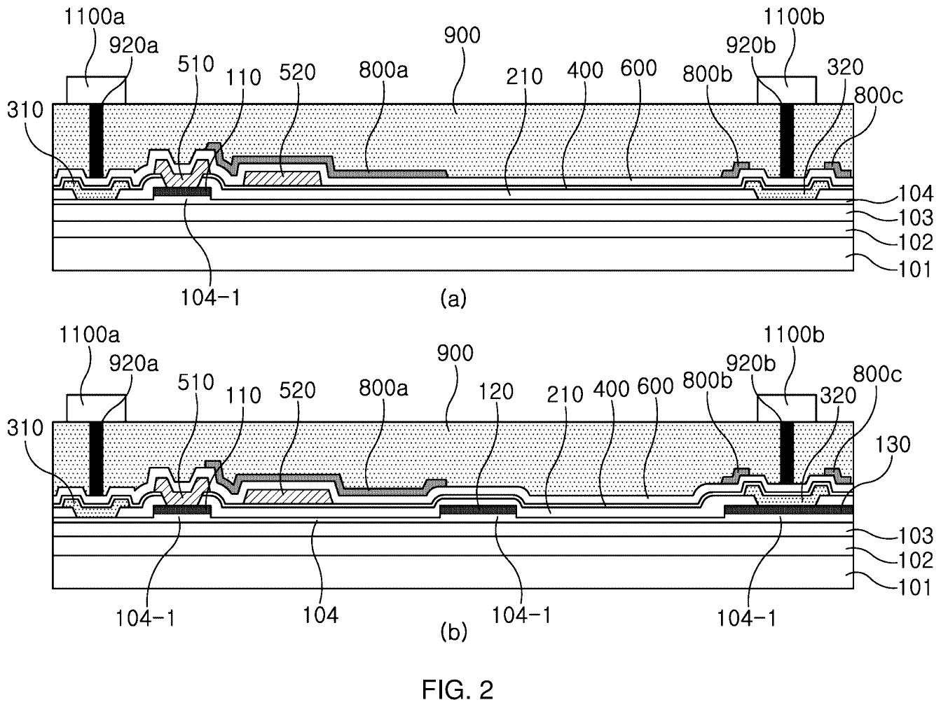

The source region 310 and the drain region 320 are formed on the left and right sides of the semiconductor substrate 100, and the gate region 510 is formed between the source region 310 and the drain region 320. The gate region 510 is formed to be closer to the source region 310. In FIG. 1, a first P—GaN layer 110 (not shown in FIG. 1 but shown in FIG. 2) having the same width as the gate region 510 is formed below the gate region 510 and appears to overlap it from a planar perspective.

The first field plate 120 and the second field plate 520 are formed between the gate region 510 and the drain region 320 to prevent an electric field from being concentrated in the gate region 510. A plurality of first field plates 120 are arranged while being spaced apart at regular intervals in the longitudinal direction. The first field plate 120 is located between the second field plate 520 and the drain region 320. The second field plate 520 is formed between the gate region 510 and the first field plate 120, and has the same or larger size as the gate region 510. From a top view perspective, the structure is arranged from left to right as the source region 310, the gate region 510, the second field plate 520, the first field plate 120, and the drain region 320.

The drain region 320 may include a P-type doped gallium nitride (P—GaN) layer 130. The P—GaN layer 130 serves as a hole injection, which will be described later. Referring to the drawings, it may be seen that the drain region 320 includes a region in which the P—GaN layer 130 is formed and a region in which the P—GaN layer 130 is not formed. Therefore, the region in which the P—GaN layer 130 is formed can be called a hole injection region, and the region in which the P—GaN layer 130 is not formed can be called a non-hole injection region.

The semiconductor device includes third field plates 800b, 800c and a fourth field plate 800a. According to an example, the fourth field plate 800a is formed extending from the gate region 510 to the first field plate 120. Therefore, it completely covers the second field plate 520 in the middle. In addition, the third field plates 800b and 800c may be configured in a symmetrical structure, spaced apart on both sides of the drain region. The width and the length of the third field plates 800b and 800c can be said to be a symmetrical structure with identical dimensions.

FIG. 2 (b) illustrates a cross-sectional view of a semiconductor device according to one or more embodiments of the present disclosure, based on the line A-A′ of FIG. 1.

The semiconductor substrate 100 may sequentially include a silicon layer 101, a GaN buffer layer 102, a GaN layer 103, an AlGaN layer 104, 104-1, and a P-type doped gallium nitride (P—GaN) layer 110. In other words, a semiconductor substrate stacked from bottom to top with a silicon layer-GaN buffer layer-GaN layer-AlGaN layer-P—GaN layer is used. As shown in the drawing, the silicon layer 101 is the thickest, and the AlGaN layer 104 is the thinnest.

As shown in FIG. 2 (a), the first passivation layer 210 may be formed on the AlGaN layers 104, 104-1 and the first P—GaN layer 110. The first passivation layer 210 is formed with a predetermined thickness in the remaining regions except the source region, the gate region, and the drain region. The first P—GaN layer 110 may be formed below the gate metal 510. Thus, the thickness of the first passivation layer in the gate region may be formed thicker than the thickness of the first passivation layer in the source region and the drain region. The first passivation layer 210 is formed to have a curved upper surface without being flat by the source region, the P—GaN, and the gate region, the drain region.

In FIG. 2 (a), the source region and the drain region are formed in direct contact with the AlGaN layer 104, whereas the gate region is not in direct contact because the first P—GaN layer 110 is formed on the AlGaN layer 104-1.

The second passivation layer 400 may be formed on the first passivation layer 210. The second passivation layer 400 is formed on the entire surface of the first passivation layer 210 including a source region 310 and a drain region 320, but excluding the gate region. This is because the gate region partially passes through the second passivation layer 400 and the first passivation layer 210 to contact the first P—GaN layer 110.

In the gate region, a gate metal 510 is formed simultaneously with a second field plate 520, and the gate metal 510 is formed to be in direct contact with the first P—GaN layer 110. The second field plate 520 is formed at a location close to the gate region and relatively far from the drain region. The second field plate 520 has a larger size than the first P—GaN layer 110. Although not shown in FIG. 2 (a), the second field plate 520 is connected to the source metal 310 or gate metal 510. This may allow the electric field in the gate edge region to be mitigated. An insulating layer 600 may be formed on the second passivation layer 400, the gate metal 510, and the second field plate 520. For example, the insulating layer 600 may be formed of SiO₂.

Third field plates 800b, 800c and fourth field plate 800a may be formed on the insulating layer 600. The fourth field plate 800a is formed from the gate region through the second field plate 520 towards the drain region. The third field plates 800b, 800c are formed correspondingly on both sides of the drain region. The fourth field plate 800a and third field plates 800b, 800c may be formed on the gate side and the drain side, respectively, to mitigate the electric fields concentrated in the gate region and the drain region. Although not shown in FIG. 2 (a), the fourth field plate 800a is connected to the source metal, and the third field plates 800b, 800c are connected to the drain metal. This allows the fields concentrated in the gate region and the drain region to be mitigated. The fourth field plate 800a has a larger size than the second field plate 520. These fourth field plate 800a and third field plates 800b, 800c may be formed of TiN, for example.

An interlayer insulating layer 900 may be formed to cover the insulating layer 600, fourth field plate 800a, and third field plates 800b, 800c. The interlayer insulation layer 900 may be made of silicon oxide (SiO₂) or a material such as TEOS, BPSG, PSG, or the like.

A plurality of contact plugs 920a, 920b may be provided to penetrate the interlayer insulating layer 900. For example, the contact plugs 920a, 920b may be made of a conductive material. The plurality of contact plugs 920a, 920b may include a source contact plug 920a in connection with a source region, and a drain contact plug 920b in connection with a drain region. Metal lines 1100a, 1100b are formed that are connected to the source contact plug 920a and the drain contact plug 920b, respectively.

FIG. 2 (b) is a cross-sectional view of a semiconductor device according to one or more embodiments of the present disclosure, being a perspective view taken along the line B-B′ of FIG. 1. Since FIG. 2 (b) is similar to the structure of FIG. 2 (a), only the different portions will be discussed.

Referring to FIG. 2 (b), the semiconductor device includes a semiconductor substrate with a stacked structure in which a silicon layer 101, a GaN buffer layer 102, a GaN layer 103, AlGaN layers 104, 104-1, and P—GaN layers 110, 130 are formed sequentially. Compared to FIG. 2 (a), the semiconductor device may further include a first field plate 120 and a second P—GaN layer 130 in the same plane as the first P—GaN layer 110.

The first field plate 120 is formed between the gate region and the drain region and serves to mitigate the electric field by dispersing the electric field concentrated at the gate. The first field plate 120 is not connected to the gate, source or drain metal and is floating. The second P—GaN layer 130 formed in the drain region serves as a hole injection to prevent performance degradation of the semiconductor device due to charge trapping during switching operations.

Next, a method of manufacturing a high-power semiconductor device according to the present disclosure will be described. Hereinafter, the manufacturing method according to the present disclosure will be described by illustrating the process state at each process step along the A-A′ line and the B-B′ line of FIG. 1. In each drawing, (a) refers to a manufacturing process along the A-A′ line, and (b) refers to a manufacturing process along the B-B′ line.

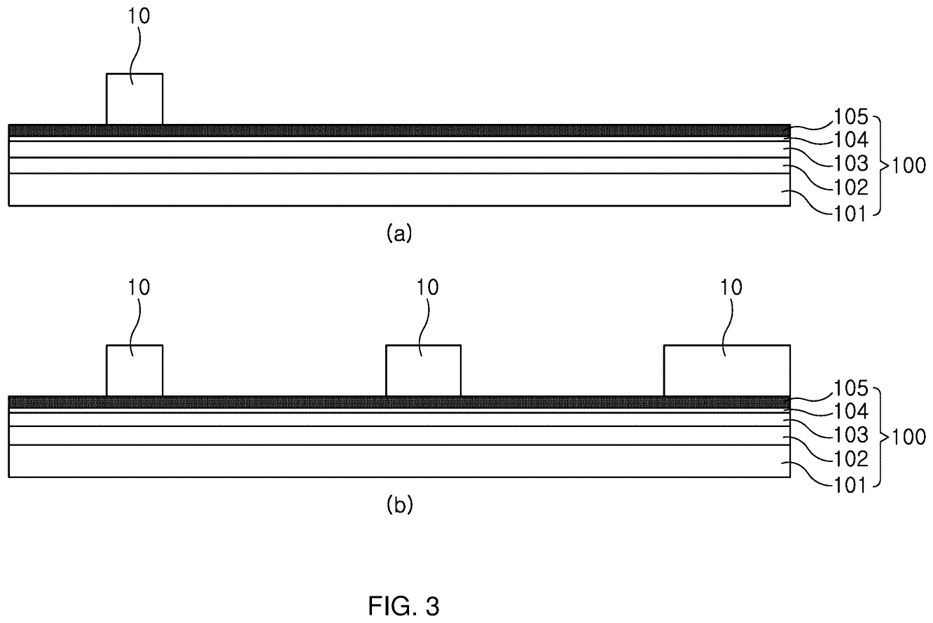

FIGS. 3 to 18 are drawings illustrating a method of manufacturing a high power semiconductor device.

Referring to FIG. 3, the semiconductor device may use a semiconductor substrate stacked with, from bottom to top, a silicon layer 101, a GaN buffer layer 102, a GaN layer 103, an AlGaN layer 104, and a P—GaN layer 105. The P—GaN layer 105 later becomes the first P—GaN layer 110 and the second P—GaN layer 130 described in FIG. 2 depending on the manufacturing process. Examples of stacking configurations of each of the above layers are omitted. It is well known to those skilled in the art to stack layers of different materials having a predetermined thickness on top of a given layer by a series of methods.

FIG. 3 (a) illustrates a process of forming a photoresist (PR) pattern 10 or hard mask on top of the P—GaN layer 105 to form a first P—GaN layer in a gate region. FIG. 3 (b) illustrates a process of forming a PR pattern 10 or hard mask on top of the P—GaN layer 105 to form a first P—GaN layer, a first field plate, and a second P—GaN layer. After forming the PR pattern 10, an etching process is performed using the PR pattern 10 as a mask to remove the P—GaN layer other than the PR pattern 10. The etching process may be performed with a hard mask as a mask instead of the PR pattern 10. The same etching process may be performed with the hard mask in place of the PR pattern 10 to form the first P—GaN layer, the first field plate, and the second P—GaN layer.

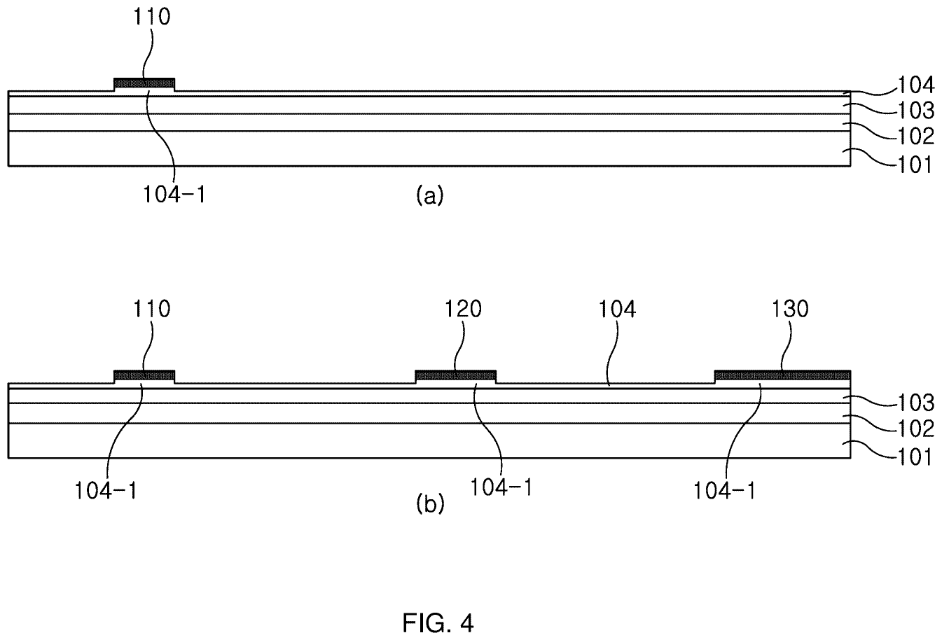

FIG. 4 illustrates a state where P—GaN layers in the remaining regions, except for the first P—GaN layer 110, the first field plate 120, and the second P—GaN layer 130, have been removed by the etching process of FIG. 3.

FIG. 4 (a) illustrates a state where only the first P—GaN layer 110 remains, and FIG. 4 (b) illustrates a state where the first P—GaN layer 110, the first field plate 120, and the second P—GaN layer 130 remain. As mentioned earlier, the second P—GaN layer 130 remaining in the drain region serves to inject holes to prevent degradation of the device due to charge trapping during semiconductor device operation. This prevents device degradation and improves reliability by preventing current collapse.

In the etching process of FIG. 3, not only the P—GaN layer 105 but also the underlying AlGaN layer 104 is slightly etched, except for the area under the PR pattern 10. Specifically, as shown in FIG. 4 (a), the thickness of the AlGaN layer 104-1 below the first P—GaN layer 110 becomes thicker than the thickness of the AlGaN layer 104 in other regions. This is because the etching process to form the first P—GaN layer 110 etches not only the P—GaN layer 105, but also the AlGaN layer 104 below the P—GaN layer 105. By over-etching the AlGaN layer 104 together in this manner, the P—GaN layer can be prevented from remaining on the AlGaN layer 104, i.e., the residual P—GaN layer 105 on the AlGaN layer 104 may be reliably prevented. If even a small amount of the P—GaN layer remains on the AlGaN layer 104, the desired device current characteristics cannot be achieved. Specifically, the residual P—GaN layer 105 can block the channel formed between the AlGaN layer 104 and the GaN layer 103 under the residual P—GaN layer.

Similarly, in FIG. 4 (b), the thickness of the AlGaN layer 104-1 under the first P—GaN layer 110, the first field plate 120, and the second P—GaN layer 130 is thicker than the thickness of the other AlGaN layers 104. This is because the AlGaN layers 104 are recessed together when the P—GaN layer 105 is etched, as described above in FIG. 4 (a).

The first field plate 120 also serves to disperse the electric field concentrated on the gate. As shown in FIG. 4 (b), the second P—GaN layer 130 in the drain region is the largest in size, and the first field plate 120 between the drain and gate regions is larger than the first P—GaN layer 110 formed in the gate region. In cross-section, the second P—GaN layer 130 in the drain region is the largest, which not only prevents device degradation due to charge traps, but also acts as a hole injection to increase reliability. As shown in FIG. 1, in plan view, the first P—GaN layer 110 (not shown in FIG. 1 but shown in FIG. 2), which is formed below the gate region 510 and appears to overlap it from a planar perspective, is the widest in the gate region. This is because the first field plate 120 is arranged with a plurality of them spaced apart in the longitudinal direction to include a region where the P—GaN layer 130 is formed (hole injection region) and a region where the P—GaN layer 130 is not formed (non-hole injection region). Similarly, the first field plate 120 also includes a plurality of longitudinally spaced apart regions in which the first field plate 120 is not formed. Current can flow through the region where the P—GaN layer 130 is not formed (non-hole injection region). Conversely, current cannot flow through the hole injection region. Creating hole injection regions with less current flow is intended to improve reliability by preventing device degradation.

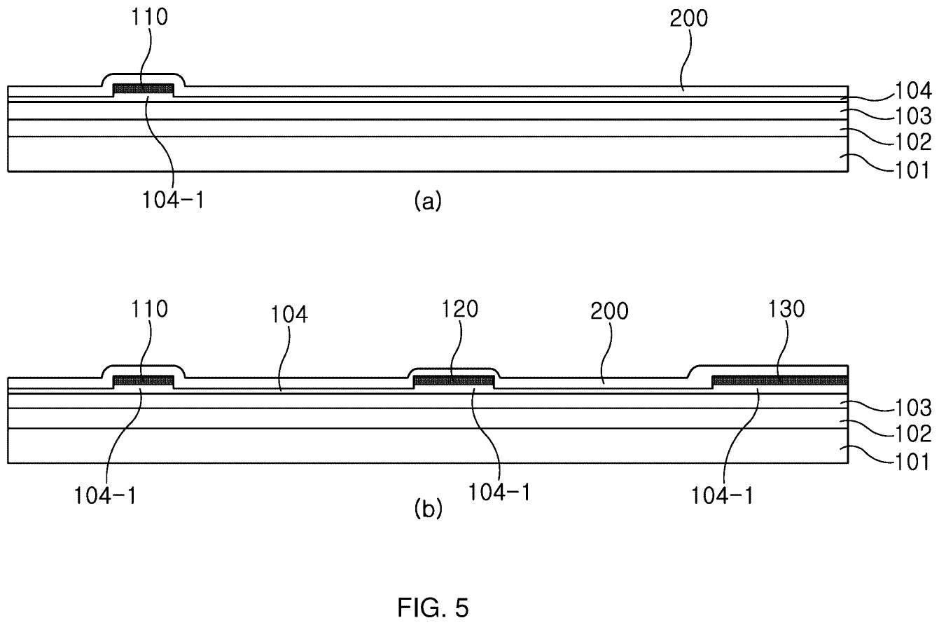

FIG. 5 illustrates a process for depositing a first passivation layer 200. Reference numeral 200 refers to the first passivation layer before the etching process. FIG. 5 (a) illustrates depositing the first passivation layer 100 on the entire surface including the first P—GaN layer 110, and FIG. 5 (b) illustrates depositing the first passivation layer 200 on the entire surface including the first P—GaN layer 110, the first field plate 120, and the second P—GaN layer 130. In examples, the first passivation layer 200 may be deposited with a thickness of 500 to 5000 Å, and the first passivation layer 200 may be one or more of SiO₂, SiN, Al₂O₃, and AlN.

In FIG. 5, when the first passivation layer 200 is deposited on the surface of the AlGaN layer 104, it is preferable to perform an ammonia plasma treatment on the surface of the AlGaN layer 104. This is because when the first passivation layer 200 is deposited, a lot of nitride (N) from the AlGaN layer 104 is lost during the etching process of the previous process (P—GaN), and it is necessary to reinforce the nitride (N) by this ammonia plasma treatment. After the ammonia plasma treatment, an annealing process may be performed at a temperature of about 500 to 1000° C. This is to restore the surface of the AlGaN layer 104 damaged during the ammonia plasma treatment. In this way, by depositing the first passivation layer 200 on the AlGaN layer 104 that has undergone the above ammonia plasma treatment and annealing process, trap sites can be prevented from forming on the AlGaN layer 104.

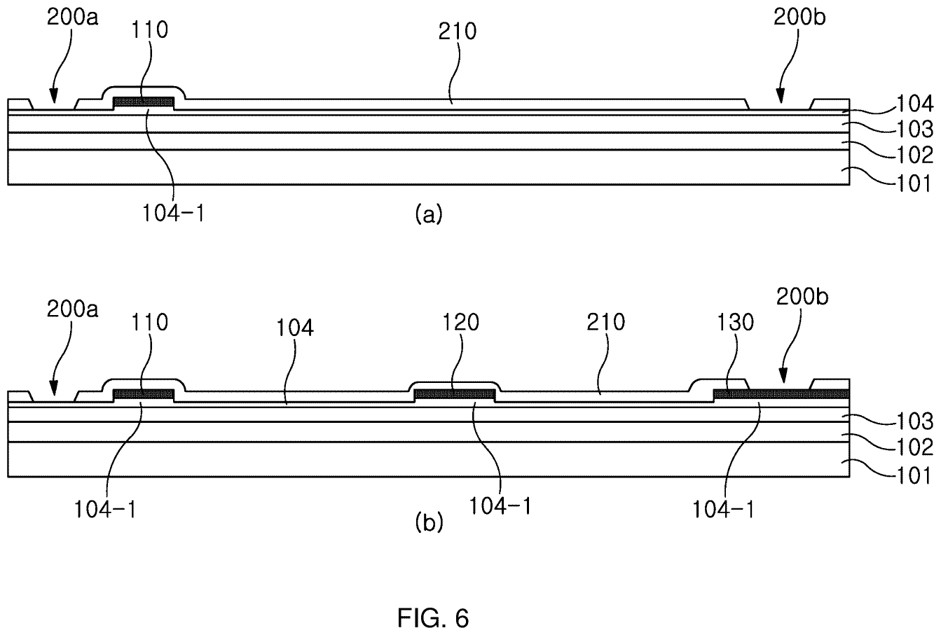

FIG. 6 illustrates a process for removing the first passivation layer in a source region and a drain region. Performing the PR patterning and etching processes sequentially on the first passivation layer 200 in the source and drain regions results in an etched first passivation layer 210. Specifically, as shown in FIG. 6 (a), the removal of the first passivation layers 200a, 200b in the source region and the drain region results in the AlGaN layer being exposed to the outside. As shown in FIG. 6 (b), the AlGaN layer in the source region is exposed to the outside, but the second P—GaN layer 130 is exposed due to the presence of the second P—GaN layer 130 in the drain region.

In FIG. 6 (a) and (b), when etching the first passivation layer in the source region, it can be etched deeper than the surface of the AlGaN layer 104, although the drawings show that it is only removed to the surface of the AlGaN layer 104. This is because a thinner AlGaN layer 104 has a lower resistance, which is effective in allowing more current to flow through it.

Also, in FIG. 6 (a), when etching the first passivation layer in the drain region as well as the source region, the AlGaN layer 104 may be etched together to be etched deeper than the surface of the AlGaN layer 104. Similarly, the smaller the thickness of the AlGaN layer 104, the lower the resistance and the more current can flow through it.

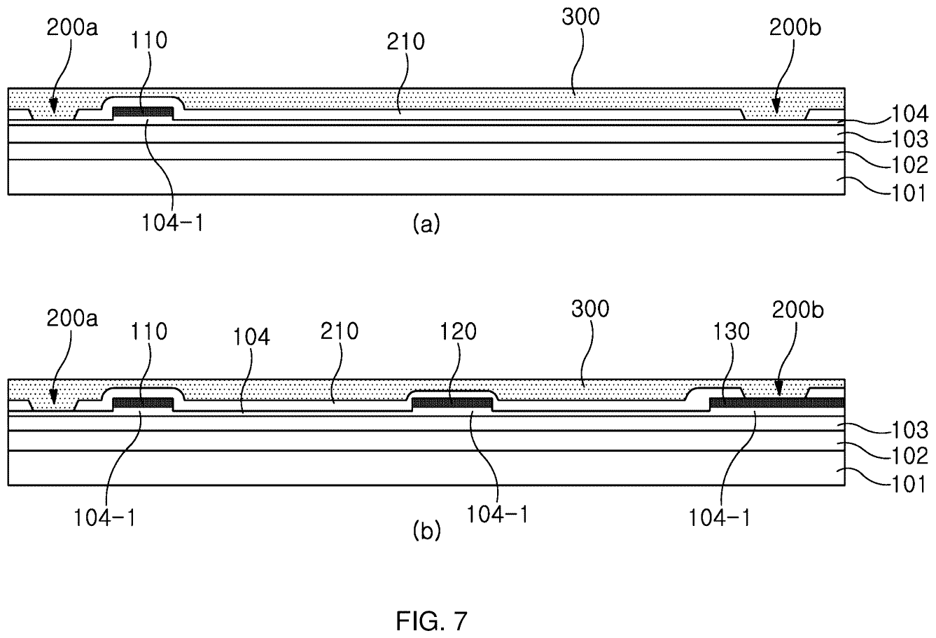

FIG. 7 illustrates a metal layer formation process for ohmic contact in the source and drain regions. Referring to FIG. 7, a metal layer 300 is formed over an entire surface of a substrate. The metal layer 300 may be a stacked structure of at least two metals. For example, Ti and Al may be deposited in sequence, and one of Au, TiN, and W may be deposited again thereon. Thus, the metal composition for ohmic contacts may be Ti/Al/Ni/Au, Ti/AI/TIN, Ti/AI/W, etc. The second Al metal may be formed thicker than the first Ti metal. For example, the thickness of the Ti metal may be 50 to 400 Å, while the thickness of the Al metal may be 500 to 3000 Å.

After the stacking process of the metal layer 300 is completed, an annealing process may be further performed. The temperature of the annealing process may be about 500 to 1000° C.

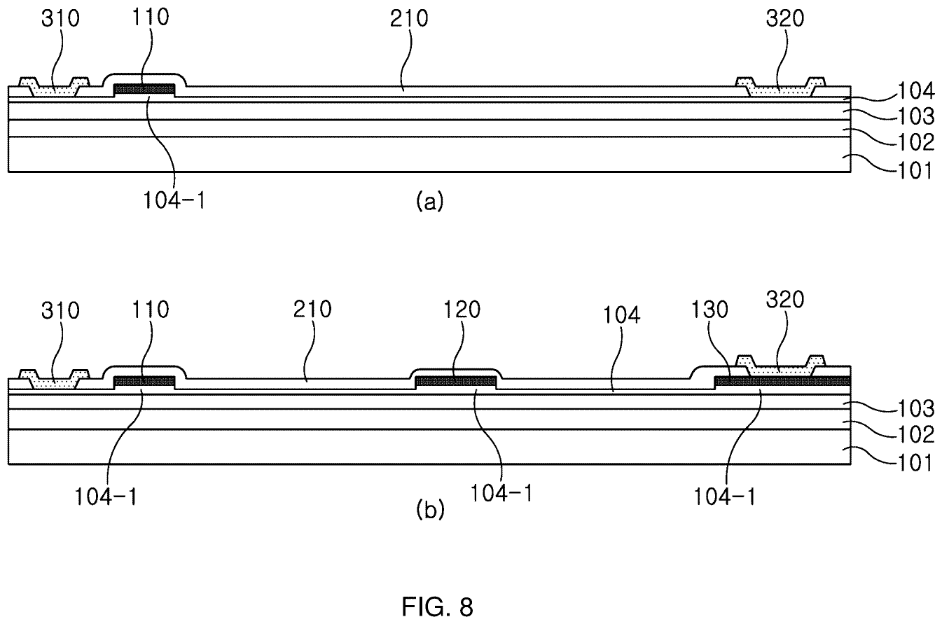

FIG. 8 illustrates a process for removing the metal layer except for the source region and the drain region. From the process result of FIG. 7, a PR pattern is formed in the source region and the drain region, and an etching process is performed using the PR pattern as a mask to remove the metal layer. Then, only the source metal 310 and the drain metal 320 remain.

In FIG. 8, the source metal 310 and drain metal 320 are formed in a shape that slightly covers both sides of the etched first passivation layer 210. In other words, they are formed to have a longer horizontal length than the etched first passivation 200a, 200b.

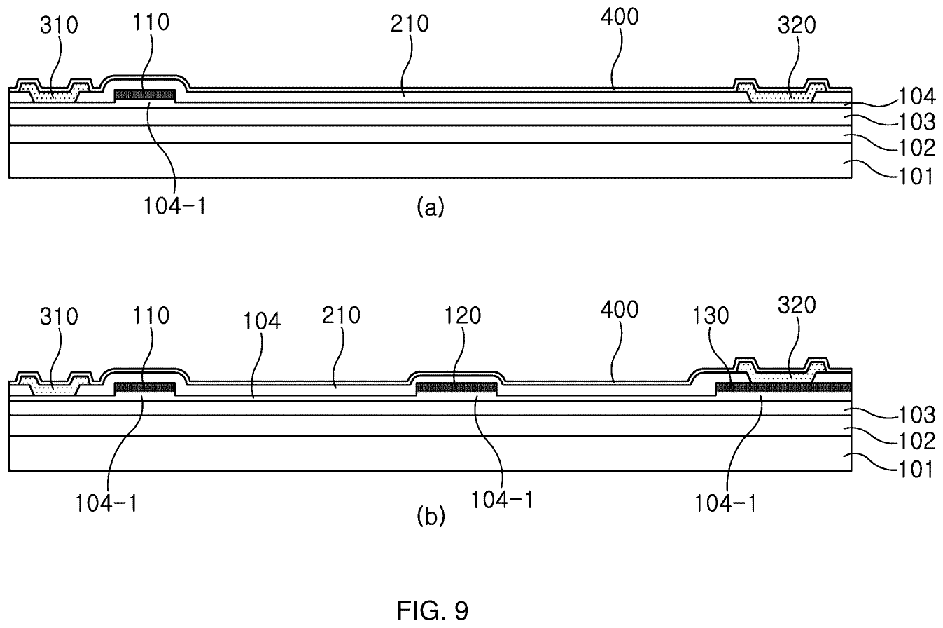

FIG. 9 illustrates a process for forming a second passivation layer 400. The second passivation layer 400 may be formed as a single layer or as a mixture of two or more layers. For example, the second passivation layer 400 may be a silicon-based high dielectric material, and may be formed of SiO₂, SiN, SiO₂/SiN, SiN/SiO₂, or the like.

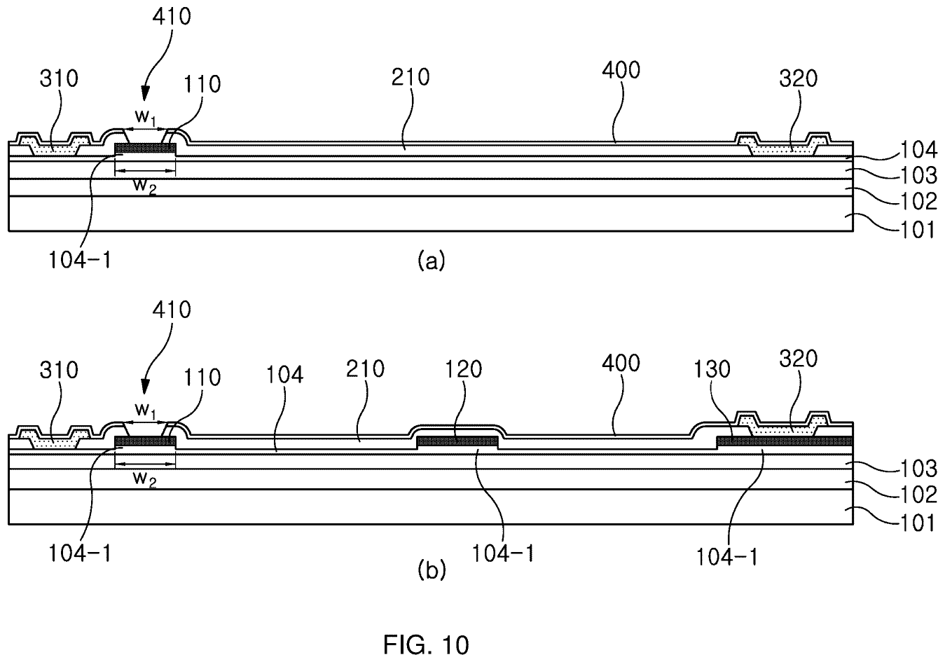

FIG. 10 illustrates a process for forming a gate contact area. In FIG. 10, a PR pattern (not shown) is formed in the gate region, and an etching process is performed using the PR pattern as a mask. This removes the second passivation layer in the gate region, forming an open gate contact region 410. Once the gate contact region 410 is formed, the underlying first P—GaN layer 110 is exposed to the outside. At this time, the gate contact region 410 may be formed to be narrower in width from top to bottom due to the nature of the etching process. In other words, the first passivation layer 210 and the second passivation layer 400 are not etched at right angles, but rather at an oblique slope. This is to provide the subsequently formed gate metal 510 with a less concentrated field at the gate edge. Specifically, the etching process of FIG. 10 causes the opening width W1 of the gate contact region 410 to be formed to be narrower than the width W2 of the underlying first P—GaN layer 110. Then, the concentration of the electric field in the edge part of the gate region during the operation of the semiconductor device can be distributed, and charge trapping occurring on the surface of the AlGaN layer near the gate region can be prevented due to this electric field relaxation.

The gate contact region is formed such that only the gate contact region 410 on the first P—GaN layer 110 is formed, leaving the remaining second passivation layer 400, including the drain region, on the opposite side.

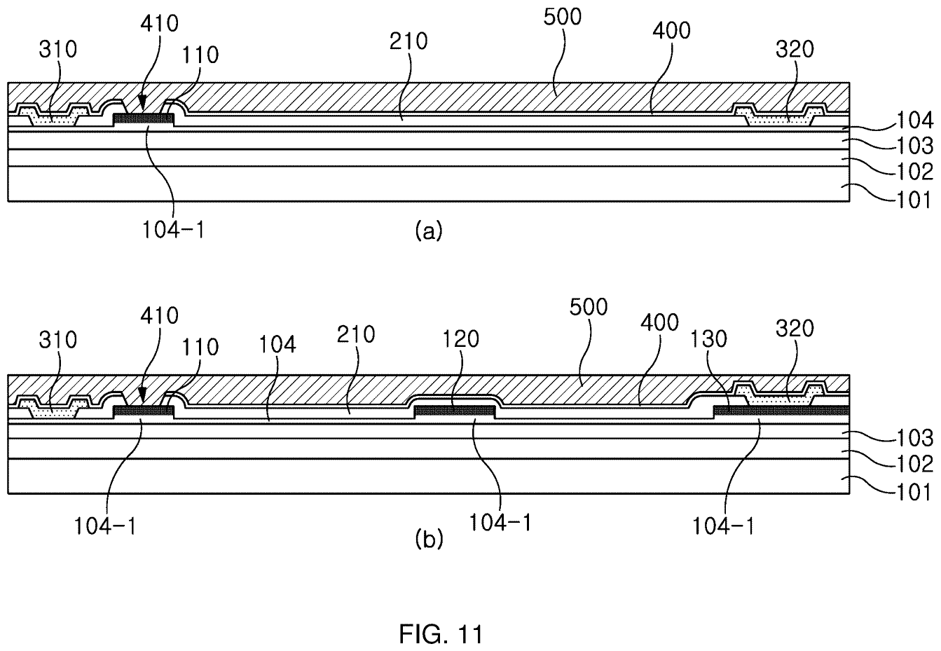

FIG. 11 illustrates a process for forming a gate metal in the gate contact region.

To form the gate metal, a metal layer 500 is formed on the entire surface of the second passivation layer 400, including the gate contact region 410. The metal layer 500 may be formed from two or more mixed layers, and according to an embodiment, may be formed by depositing Ti—TiN—Al in order. The Ti layer has a thickness of 50 to 400 Å, the TiN layer has a thickness of 50 to 400 Å, and the Al layer has a thickness of 1000 to 3000 Å, respectively.

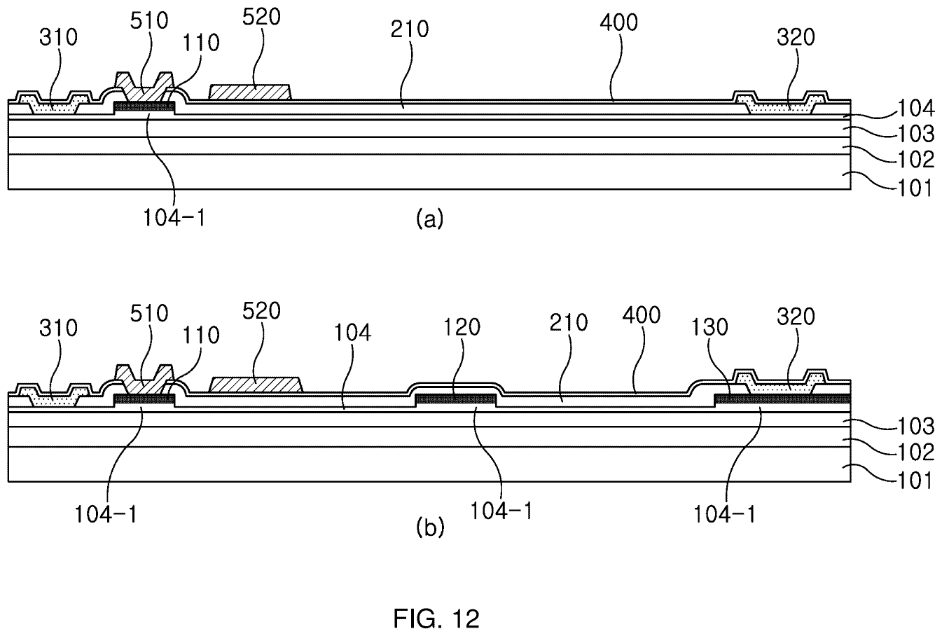

FIG. 12 illustrates a process for forming a gate contact region and a second field plate.

In FIG. 12, a PR pattern (not shown) is formed in the area where the gate metal 510 and the second field plate 520 are to be formed in FIG. 11, and an etching process is performed using the PR pattern as a mask. By the etching process, the metal layer formed in the remaining areas except the area where the gate metal 510 and the second field plate 520 are to be formed is removed. The gate metal 510 formed by the etching process is of the same width and size as the first P—GaN layer 110 formed below. As shown in FIG. 12, it can be seen that when forming the gate metal 510, the second field plate 520 is formed together, i.e., the second field plate 520 can be formed without forming additional masks or layers. The second field plate 520 is located between the gate region and the drain region, and is formed at a position closer to the gate region. The second field plate 520 may prevent an electric field from being concentrated in the gate region when the semiconductor device is operating. The second field plate 520 is wider than the gate metal 510 with which it is formed. Since the second field plate 520 is not only closer to the gate region but also has a larger size, it can effectively prevent the electric field from concentrating on the gate. Additionally, the second field plate 520 and the gate metal 510 are made of the same material.

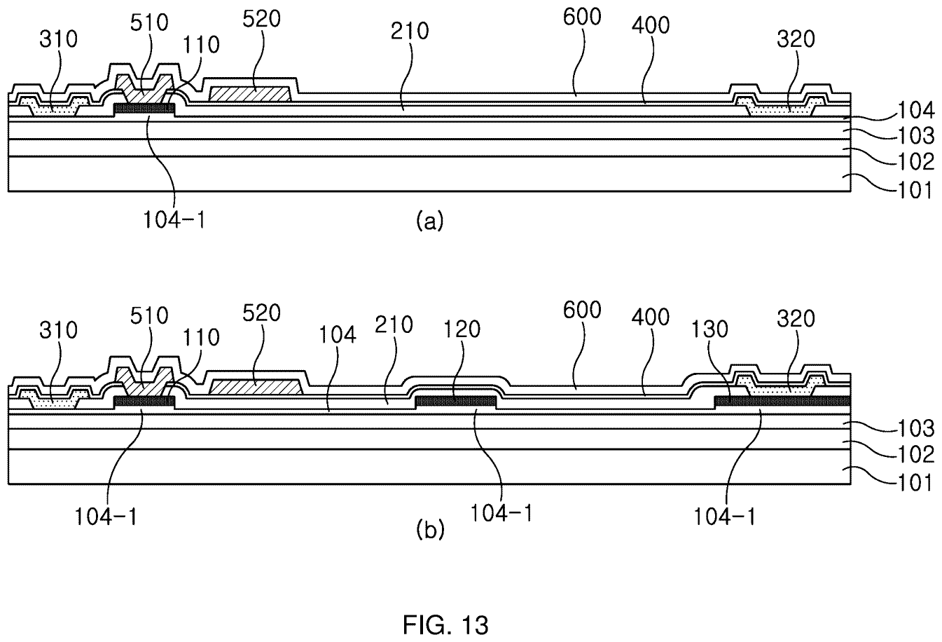

FIG. 13 illustrates a process for forming an insulating layer.

After the gate metal 510 and the second field plate 520 are formed, an insulating layer 600 is formed above the second passivation layer 400. The insulating layer 600 may be SiO2, and has a thickness of 1000 to 5000 Å.

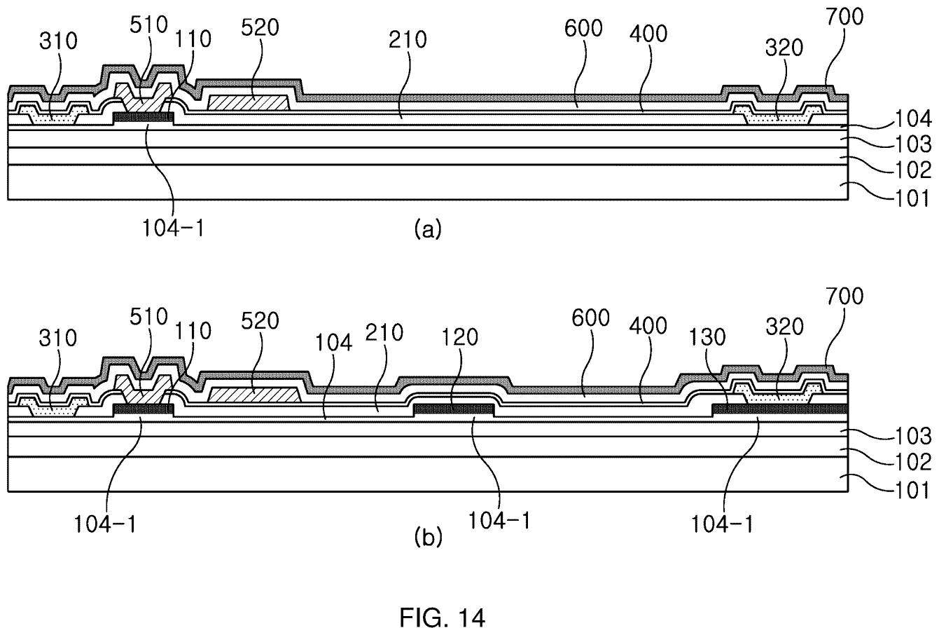

FIG. 14 illustrates a process for depositing a field plate metal 700 on the insulating layer 600. The field plate metal 700 is a pre-process for forming third field plates in a subsequent process. In an example, the metal 700 for forming the third field plates is formed by depositing TiN at about 1000 to 5000 Å, but it may be formed by depositing Al. In other words, it need not be limited to depositing TiN or Al, as long as the material is capable of mitigating the field.

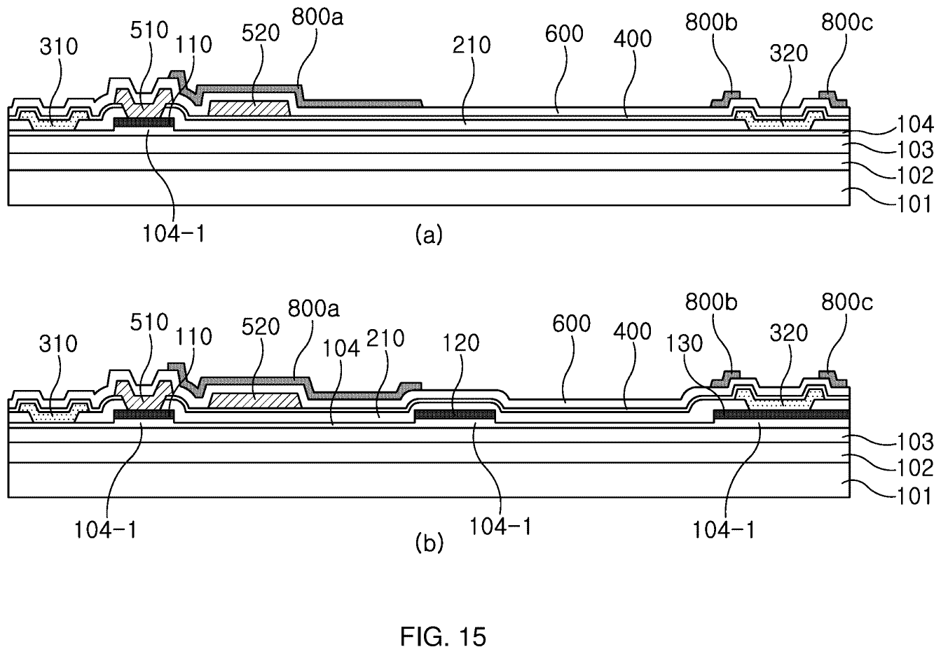

FIG. 15 illustrates a process for forming a fourth field plate 800a and third field plates 800b, 800c.

A part of the field plate metal 700 formed on the insulating film 600 is etched and removed according to the process of FIG. 14. Specifically, the field plate metal formed from the gate metal 510 to the first field plate 120 and the rest of the drain metal 320 except for some parts of both sides is removed.

The fourth field plate 800a and third field plates 800b, 800c are formed according to the etching process. Specifically, the fourth field plate 800a is formed to overlap the gate metal 510, the second field plate 520, and the first field plate 120. The third field plates 800b and 800c are formed to overlap portions of both sides of the drain metal 320 and are formed to have the same size as the second P—GaN layer 130 formed below. This allows the fourth field plate 800a and the third field plates 800b, 800c to mitigate the electric field concentration phenomenon in the gate region and the drain region.

As shown in FIG. 15, the fourth field plate 800a and the third field plates 800b, 800c are formed simultaneously in the gate region and the drain region. Thus, compared to forming field plates for the gate region and the drain region separately, the electric field concentrated at the gate and the drain can be mitigated without forming additional masks or layers.

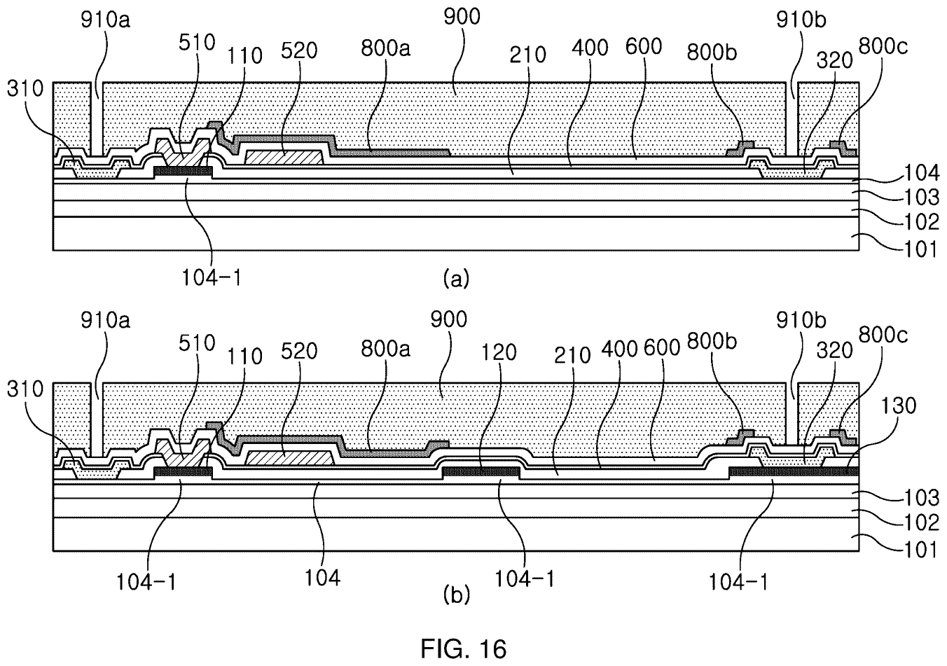

FIG. 16 illustrates a process for forming an interlayer insulating layer 900.

FIG. 16 illustrates that after the fourth field plate 800a and the third field plates 800b, 800c were formed, the interlayer insulating layer 900 was formed with a thickness of about 10000 to 30000 Å, and the interlayer insulating film was subsequently flattened by a CMP process. Further, the regions 910a, 910b where the contact plugs are to be formed for electrode connection were formed by performing an etching process.

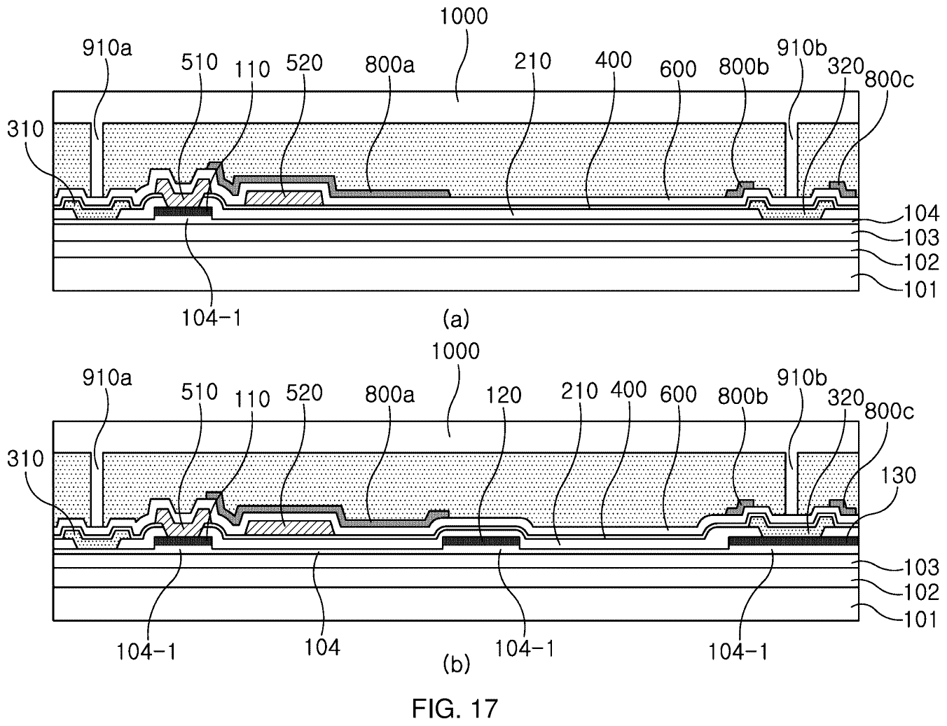

FIG. 17 illustrates a process for forming metal to form a metal line.

FIG. 17 illustrates a state in which a metal for a metal line 1000 is deposited at a predetermined thickness on an interlayer insulating layer 900. The metal for a metal line 1000 is also provided in the regions 910a and 910b. Metal formed in the regions 910a and 910b becomes a source contact plug 920a and a drain contact plug 920b.

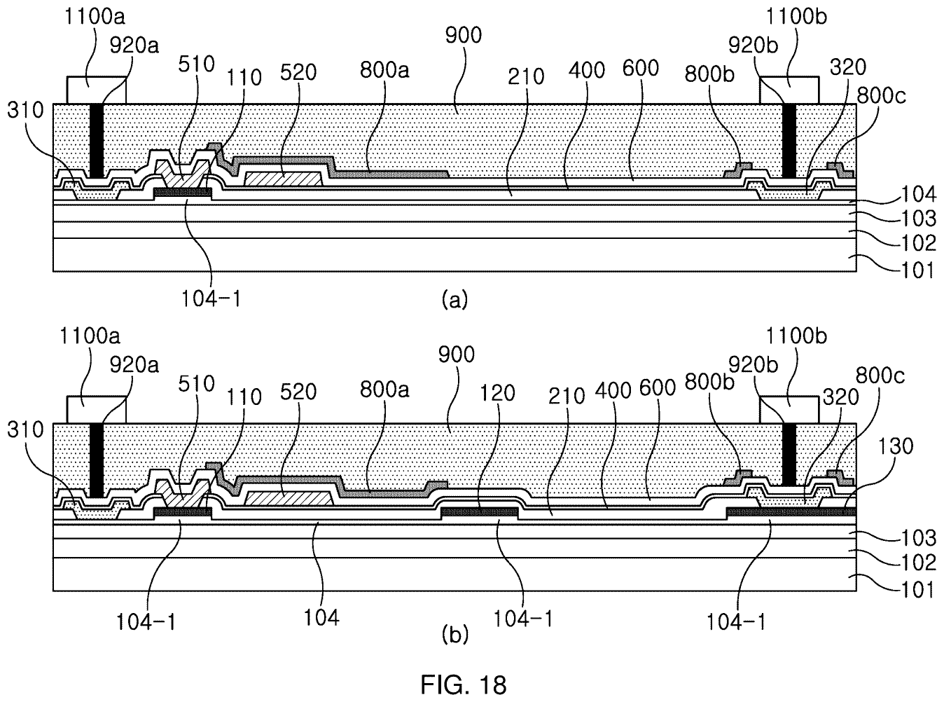

Thereafter, a PR patterning and etching process is performed to remove the remaining regions except for the electrode portions. As a result, metal lines 1100a, 1100b connecting with the source contact plug 920a and the drain contact plug 920b, respectively, are formed. Thus, a semiconductor device with a structure as shown in FIG. 18 (as shown in FIG. 2) may be finally manufactured.

Although not shown in FIG. 18, the source contact plug 920a may be connected to the second field plate 520 and the fourth field plate 800a through a metal line to alleviate an electric field around the gate area.

In addition, the drain contact plug 920b is connected to the third field plates 800b, 800c through a metal line to alleviate the electric field around the drain.

As described above, it can be understood that the present disclosure relates to manufacturing a semiconductor device using gallium nitride (GaN) materials having superior properties compared to silicon materials.

According to the present disclosure, GaN-based semiconductor devices are expected to exhibit improved performance and excellent compatibility in high-power devices that exceed the performance of conventional silicon-based semiconductor devices.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A method of manufacturing a high power semiconductor device, the method comprising:
preparing a semiconductor substrate on which a silicon layer, a gallium nitride (GaN) buffer layer, a GaN layer, an aluminum gallium nitride (AlGaN) layer, and a P—GaN layer are sequentially stacked;
etching the P—GaN layer and then simultaneously forming a first P—GaN layer, a first field plate, and a second P—GaN layer on a surface of the AlGaN layer;
forming a first passivation layer on the semiconductor substrate;
etching the first passivation layer and then forming a source metal and a drain metal;
forming a second passivation layer after forming the source metal and the drain metal;
forming a gate metal in a gate contact region formed by etching the second passivation layer;
forming an insulating layer after the forming of the gate metal;
forming a field plate metal on the insulating layer; and
forming third field plates on both sides of the drain metal and a fourth field plate between the gate metal and the first field plate by performing an etching process on the field plate metal.

2. The method of claim 1, further comprising:
before forming the first passivation layer,
performing an ammonia plasma treatment on a surface of the AlGaN layer; and
performing an annealing process after the ammonia plasma treatment.

3. The method of claim 1, wherein the first passivation layer is formed of at least one of SiO₂, SiN, Al₂O₃, and aluminum nitride (AlN).

4. The method of claim 1, wherein the second passivation layer is formed by combining one or more high dielectric thin films, and
wherein any one of SiO₂/SiN, SiN/SiO₂, SiN/SiO₂/SiN, SiO₂/SiN/SiO₂, Al₂O₃, and aluminum nitride (AlN) is selected to form the second passivation layer.

5. The method of claim 1, wherein the gate contact region formed by the etching of the second passivation layer has an opening width smaller than an opening width of the first P—GaN layer.

6. The method of claim 1, wherein the source metal is formed to have a smaller width than the drain metal.

7. The method of claim 1, wherein the source metal and the drain metal are formed of one of Ti/Al/Ni/Au, Ti/Al/TiN, and Ti/Al/W, and
wherein the Ti metal has a thickness of 50 to 400 Å, and the Al metal has a thickness of 500 to 3000 Å.

8. The method of claim 1, wherein a second field plate is simultaneously formed when the gate metal is formed, and is formed closer to the gate metal than the first field plate.

9. The method of claim 1, further comprising:
after the forming of the third field plates and the fourth field plate,
forming an interlayer insulating layer;
patterning the interlayer insulating layer and then forming a contact plug; and
forming a metal line connected to the contact plug.

10. The method of claim 1, wherein the semiconductor device comprises a drain region having a hole injection region and a non-hole injection region, and
wherein the second P—GaN layer is located in the hole injection region.

11. A method of manufacturing a high power semiconductor device, the method comprising:
stacking and forming a AlGaN layer and a P—GaN layer on a semiconductor substrate;
etching the P—GaN layer and then simultaneously forming a gate P—GaN layer, a first field plate, and a drain P—GaN layer on a surface of the AlGaN layer;
treating the surface of the AlGaN layer with a plasma;
forming a first passivation layer on the surface-treated AlGaN layer and the semiconductor substrate;
etching the first passivation layer and then forming a source metal and a drain metal;
forming a second passivation layer on the source and drain metals and the first passivation layer;
etching the second passivation layer and then simultaneously forming a gate metal and a second field plate;
forming an insulating layer after the forming of the gate metal and the second field plate;
forming third field plates on both sides of the drain metal and a fourth field plate between the gate metal and the first field plate;
forming an interlayer insulating layer on the third field plates and the fourth field plate;
patterning the interlayer insulating layer and then forming a contact plug; and
forming a metal line connected to the contact plug.

12. The method of claim 11, wherein the forming of the gate metal comprises forming a gate contact region, and
wherein an opening width of the gate contact region is formed to be smaller than an opening width of the gate P—GaN layer.

13. The method of claim 11, wherein the source metal is formed to have a smaller width than the drain metal.

14. The method of claim 11, wherein the first passivation layer is formed of at least one of SiO₂, SiN, Al₂O₃, and aluminum nitride (AlN).

15. The method of claim 11, wherein the second passivation layer is formed by combining one or more high dielectric thin films, and
wherein any one of SiO₂/SiN, SiN/SiO₂, SiN/SiO₂/SiN, SiO₂/SiN/SiO₂, Al₂O₃, and aluminum nitride (AlN) is selected to form the second passivation layer.

16. The method of claim 11, further comprising:
performing a heat treatment on the surface of the AlGaN layer after the surface is treated with the plasma.

17. The method of claim 11, wherein the semiconductor device comprises a drain region having a hole injection region and a non-hole injection region, and
wherein the drain P—GaN layer is located in the hole injection region to operate as a hole injection.

18. The method of claim 11, wherein the gate metal is formed in contact with an upper surface of the gate P—GaN layer, and
wherein a width of the gate metal is equal to a width of the gate P—GaN layer.

19. The method of claim 11, wherein the drain metal is formed in contact with an upper part of the drain P—GaN layer, and
wherein a width of each of the third field plates formed on an upper part of the drain metal is equal to a width of the drain P—GaN layer.

20. The method of claim 11, wherein the AlGaN layer formed below the gate P—GaN layer, the first field plate, and the drain P—GaN layer is thicker than other regions of the P—GaN layer.
